(19) United States
(12) Patent Application Publication
(10) Pub. No.: US 2024/0316709 A1
(43) Pub. Date: Sep. 26, 2024

(54) TOOL CHANGING APPARATUS AND METHOD

(71) Applicant: SEMES CO., LTD., Cheonan-si (KR)

(72) Inventors: Changhoon OK, Cheonan-si (KR); Yonghyun LEE, Cheonan-si (KR)

(73) Assignee: SEMES CO., LTD., Cheonan-si (KR)

(21) Appl. No.: 18/584,446

(22) Filed: Feb. 22, 2024

(30) Foreign Application Priority Data
Mar. 23, 2023 (KR) 10-2023-0037980

(51) Int. Cl. B23Q 3/155; B23Q 3/06; H01L 21/67

(52) U.S. Cl. CPC B23Q 3/1554; B23Q 3/069; B23Q 3/15503; B23Q 3/15553; H01L 21/67121; H01L 21/67271

(57) ABSTRACT

Provided is a tool changing apparatus and method capable of easily and safely changing various tools usable for a table device or a pickup device of an equipment depending on materials such as semiconductor chips or semiconductor packages, the tool changing apparatus including a target tool detachably mountable on an equipment depending on a type or size of semiconductor chips or semiconductor packages, and a coupling device mounted between the equipment and the target tool to detachably fix the target tool to the equipment, wherein the coupling device includes a stud mounted on the target tool or the equipment, and a clamping module mounted in the equipment or the target tool to clamp the stud.

### CROSS-REFERENCE TO RELATED PATENT APPLICATION

This application claims the benefit of Korean Patent Application No. 10-2023-0037980, filed on Mar. 23, 2023, in the Korean Intellectual Property Office, the disclosure of which is incorporated herein in its entirety by reference.

### BACKGROUND OF THE INVENTION

### 1. Field of the Invention

The present invention relates to a tool changing apparatus and method and, more particularly, to a tool changing apparatus and method capable of easily and safely changing various tools usable for a table device or a pickup device of an equipment depending on materials such as semiconductor chips or semiconductor packages.

### 2. Description of the Related Art

In general, semiconductor devices may be formed on a silicon wafer used as a semiconductor substrate by repeatedly performing a series of manufacturing processes, and then produced into a semiconductor strip including a plurality of semiconductor packages through dicing, die bonding, and molding processes.

The semiconductor strip may be individualized into a plurality of semiconductor packages and then the semiconductor packages may be sorted into non-defective or defective products through a sawing and sorting process. For example, an apparatus for performing the sawing and sorting process may include a sawing module for loading the semiconductor strip onto a chuck table and then individualizing the semiconductor strip into a plurality of semiconductor packages by using a sawing blade, and a sorting module for cleaning and drying the individualized semiconductor packages, inspecting the semiconductor packages by using an inspection camera, and sorting and unloading the semiconductor packages based on the inspection result.

An existing semiconductor sawing and sorting equipment may changeably use various tools for a table device or a pickup device of the equipment depending on the shape or type of materials so as to be compatible with various semiconductor chips or semiconductor packages.

According to the existing equipment, in order to change a tool, a user manually bolts and assembles the tool to the equipment or manually fixes the tool by using lockers, e.g., locking clips, mounted on the equipment. However, because the above methods all depend on manual operation of the user, at least two users may be required for downward or upward assembly, e.g., one for lifting the tool and another for bolting, a long time may be taken to change the tool, the burden on the user or the difficulty of the operation may be increased due to a recent increase in tool weight and volume, and the tool may not be easily stably fixed to frequently cause the dislocation or dropping of the tool.

### SUMMARY OF THE INVENTION

The present invention provides a tool changing apparatus and method capable of automating tool changing operation by using air clamping, reducing user burden, increasing operation safety, and significantly reducing labor and time for operation. However, the above description is an example, and the scope of the present invention is not limited thereto.

According to an aspect of the present invention, there is provided a tool changing apparatus including a target tool detachably mountable on an equipment depending on a type or size of semiconductor chips or semiconductor packages, and a coupling device mounted between the equipment and the target tool to detachably fix the target tool to the equipment, wherein the coupling device includes a stud mounted on the target tool or the equipment, and a clamping module mounted in the equipment or the target tool to clamp the stud.

The equipment may be a semiconductor sawing and sorting equipment for sawing and sorting the semiconductor chips or the semiconductor packages.

The stud may include a head provided at a front end of the stud so as to be at least partially inserted into the clamping module, and having a first width, and a neck provided at a rear of the head and having a second width less than the first width.

The clamping module may include a module body provided with a stud hole having a shape corresponding to the stud to accommodate the stud, a movable clamping structure mounted in the module body to move toward or away from the neck of the stud inserted into the stud hole, and a forward/backward device for moving the movable clamping structure forward or backward.

The movable clamping structure may be at least one of a ball, a ring, a roller, a protrusion, a bump, and combinations thereof.

The forward/backward device may include a pressing member for pressing the movable clamping structure at a first position to maintain a forward state and clamp the stud, and releasing the movable clamping structure at a second position to set the stud free, an elastic spring for providing an elastic restoring force in a direction in which the pressing member moves to the first position, and a pressing member moving device for selectively moving the pressing member from the first position to the second position against the elastic restoring force of the elastic spring.

The pressing member moving device may include a pressure transmission line for moving the pressing member to the second position by using hydraulic or pneumatic pressure.

The pressing member moving device may include a solenoid device for moving the pressing member to the second position by using magnetic force.

The tool changing apparatus may further include a sensor for detecting a coupling state between the stud and the clamping module or a state of a pressure transmission line connected to the clamping module, and a controller for receiving a normal coupling signal or a pressure state signal from the sensor and outputting notification information.

According to another aspect of the present invention, there is provided a tool changing method including (a) placing a target tool provided with a stud so as to be detachably mountable on an equipment depending on a type or size of semiconductor chips or semiconductor packages, on standby at a target position, (b) releasing a clamped mode to a free mode by transmitting a hydraulic or pneumatic pressure or applying an electrical signal to a clamping module, such that the stud is insertable into the clamping module mounted in the equipment, (c) inserting the stud into the clamping module by moving the target tool toward the equipment or controlling the equipment to move toward the target tool, and (d) switching the free mode to the clamped mode by interrupting the transmission of the hydraulic or pneumatic pressure or the application of the electrical signal to the clamping module so as to allow the clamping module to clamp the stud.

### BRIEF DESCRIPTION OF THE DRAWINGS

The above and other features and advantages of the present invention will become more apparent by describing in detail embodiments thereof with reference to the attached drawings in which:

FIG. 1 is a plan view of a semiconductor sawing and sorting apparatus to which a tool changing apparatus according to some embodiments of the present invention is applicable;

FIG. 2 is an exploded perspective view of a tool changing apparatus according to some embodiments of the present invention;

FIG. 3 is an assembled perspective view of the tool changing apparatus of FIG. 2;

FIG. 4 is a cross-sectional view showing a free mode between a stud and a clamping module of the tool changing apparatus of FIG. 3;

FIG. 5 is a cross-sectional view showing a clamped mode between a stud and a clamping module of the tool changing apparatus of FIG. 4;

FIG. 6 is a cross-sectional view of a tool changing apparatus according to other embodiments of the present invention;

FIG. 7 is a cross-sectional view of a tool changing apparatus according to other embodiments of the present invention;

FIG. 8 is a cross-sectional view of a tool changing apparatus according to other embodiments of the present invention;

FIG. 9 is an exploded perspective view of a tool changing apparatus according to other embodiments of the present invention;

FIG. 10 is an assembled perspective view of the tool changing apparatus of FIG. 9; and

FIG. 11 is a flowchart of a tool changing method according to some embodiments of the present invention.

### DETAILED DESCRIPTION OF THE INVENTION

Hereinafter, the present invention will be described in detail by explaining embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the thicknesses or sizes of layers are exaggerated for clarity and convenience of explanation.

The terminology used herein is for the purpose of describing particular embodiments and is not intended to limit the invention. As used herein, the singular forms “a”, “an”, and “the” are intended to include the plural forms as well, unless the context clearly indicates otherwise. It will be further understood that the terms “comprises” and/or “comprising”, when used in this specification, specify the presence of stated features, integers, steps, operations, elements, components, and/or groups thereof, but do not preclude the presence or addition of one or more other features, integers, steps, operations, elements, components, and/or groups thereof.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, the embodiments of the invention should not be construed as limited to the particular shapes of regions illustrated herein, but are to include deviations in shapes that result, for example, from manufacturing.

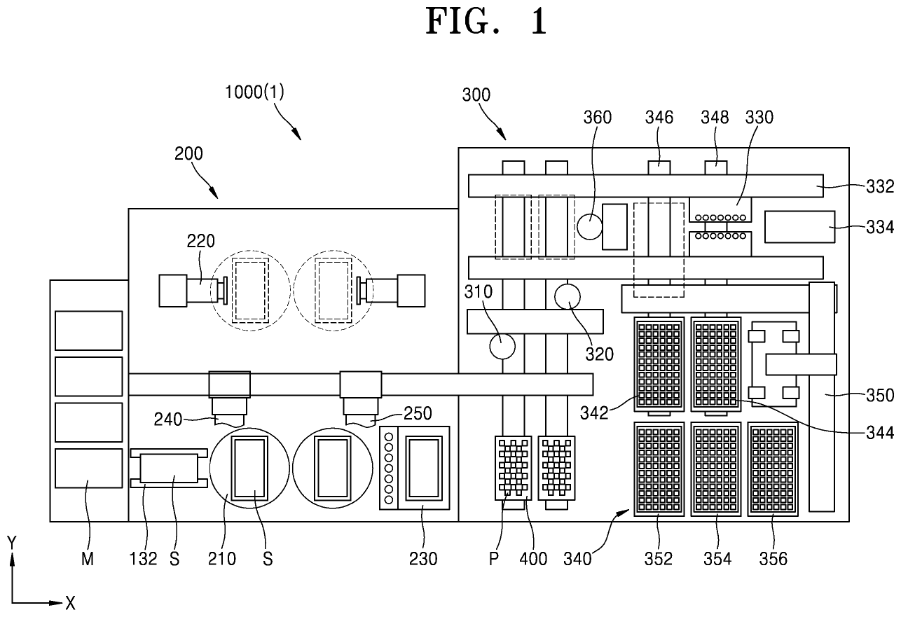

FIG. 1 is a plan view of a semiconductor sawing and sorting apparatus 1000 to which a tool changing apparatus according to some embodiments of the present invention is applicable.

As shown in FIG. 1, the semiconductor sawing and sorting apparatus 1000 to which the tool changing apparatus according to some embodiments of the present invention is applicable is an equipment 1 for sawing and sorting semiconductor chips or semiconductor packages, and may include a sawing module 200 for sawing and individualizing a semiconductor strip S into a plurality of semiconductor packages P, and a sorting module 300 for inspecting the semiconductor packages P and sorting the semiconductor packages P based on the inspection result.

The sawing module 200 may include a chuck table 210 for supporting the semiconductor strip S, a sawing unit 220 for sawing and individualizing the semiconductor strip S on the chuck table 210 into the semiconductor packages P, and a cleaning and drying unit 230 for cleaning and drying the individualized semiconductor packages P. For example, a magazine M storing a plurality of semiconductor strips S may be disposed at a side of the sawing module 200. Although not specifically shown in the drawings, a gripper (not shown) may be provided to unload the semiconductor strip S from the magazine M, and the semiconductor strip S unloaded from the magazine M may be guided by guide rails 132.

The semiconductor strip S unloaded onto the guide rails 132 may be picked up by a strip picker 240 and then transferred onto the chuck table 210, and the chuck table 210 may be moved to under the sawing unit 220 after the transfer of the semiconductor strip S is completed. The sawing unit 220 may include a circular blade for sawing the semiconductor strip S. For example, the circular blade may be moved in an X-axis direction, and the chuck table 210 may be moved in a Y-axis direction.

The semiconductor packages P individualized by the sawing unit 220 may be picked up and transferred by a package picker 250. The package picker 250 may be configured to move in vertical and horizontal directions, and pick up the semiconductor packages P and move the semiconductor packages P to above the cleaning and drying unit 230. The cleaning and drying unit 230 may remove foreign substances from the semiconductor packages P by using a brush and a cleaning liquid, and dry the semiconductor packages P by ejecting air onto the semiconductor packages P.

In addition, the package picker 250 may transfer the cleaned and dried semiconductor packages P to the sorting module 300.

Although not shown in the drawings, for example, the sorting module 300 may include an inversion table (not shown) on which the semiconductor packages P are placed, and the inversion table may include vacuum holes for vacuum-sucking the semiconductor packages P. The semiconductor packages P may be transferred onto the inversion table by the package picker 250, and the inversion table may be configured to move in the horizontal direction, e.g., the Y-axis direction. A first inspection camera 310 for inspecting the semiconductor packages P on the inversion table may be disposed above a path of the inversion table to move in the horizontal direction, e.g., the X-axis direction. The first inspection camera 310 may image and inspect a first side of the semiconductor packages P on the inversion table, e.g., a first side of the semiconductor packages P on which connection pads or solder bumps are provided.

A pallet table 400 for transferring the semiconductor packages P may be disposed below the inversion table, and the semiconductor packages P may be inverted by the inversion table and then carried onto the pallet table 400. In this case, the semiconductor packages P may be placed on the pallet table 400 with a second side facing up. The pallet table 400 may be configured to move in the horizontal direction, e.g., the Y-axis direction, and a second inspection camera 320 for inspecting the second side of the semiconductor packages P may be disposed above a path of the pallet table 400. In this case, the second inspection camera 320 may be configured to move in the horizontal direction, e.g., the X-axis direction.

Meanwhile, based on the illustration, two pallet tables 400 may be used and, in this case, two inversion tables may be used to correspond to the two pallet tables 400. However, the number of the pallet tables 400 and the inversion tables may vary and thus the scope of the present invention is not limited thereby.

After the inspection by the second inspection camera 320 is completed, the pallet table 400 may be moved to an area for sorting the semiconductor packages P, and a plurality of pickers 330 for transferring the semiconductor packages P may be disposed above the area for sorting to move in the horizontal direction, e.g., the X-axis direction. The sorting module 300 may further include a tray supplier 340 for supplying trays 342 and 344 for sorting and storing the semiconductor packages P based on the inspection result. For example, the tray supplier 340 may supply first trays 342 for storing the semiconductor packages P which are determined as non-defective products based on the inspection result, and second trays 344 for storing the semiconductor packages P to be reworked based on the inspection result.

The tray supplier 340 may include first and second tray transfer units 346 and 348 for transferring the first and second trays 342 and 344, respectively, and a tray supply unit 350 for supplying the first and second trays 342 and 344 to the first and second tray transfer units 346 and 348. The tray supplier 340 may further include a first stacker 352 for storing the first trays 342 containing the non-defective semiconductor packages, a second stacker 354 for storing the second trays 344 containing the semiconductor packages to be reworked, and a third stacker 356 loaded with empty trays.

Meanwhile, the pickers 330 may be configured to be moved in the horizontal and vertical directions by a picker driver 332, and a collection bin 334 for collecting the defective semiconductor packages determined based on the inspection result may be disposed at a side of the picker driver 332. A lower camera 360 for imaging the semiconductor packages P picked up by the pickers 330 may be disposed below a path of the pickers 330, and locations for storing the semiconductor packages P may be determined using images captured by the lower camera 360.

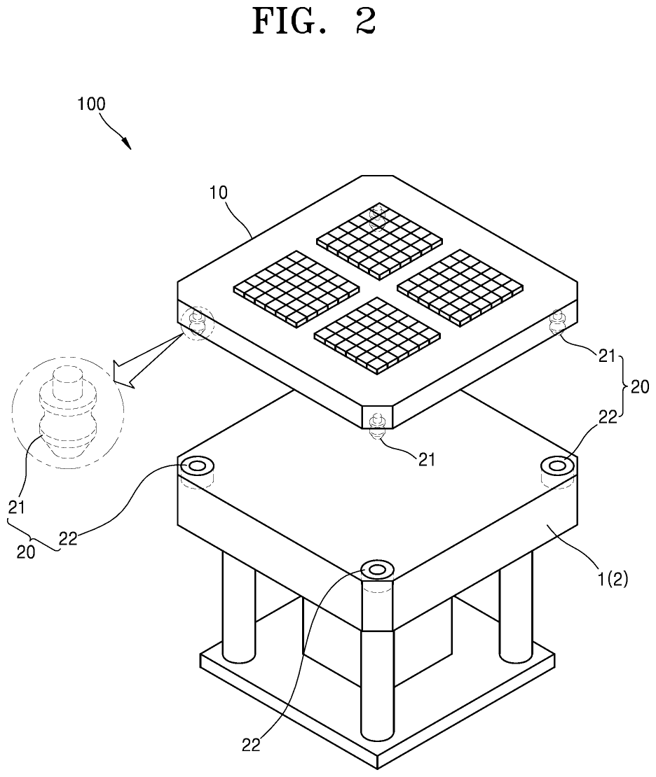

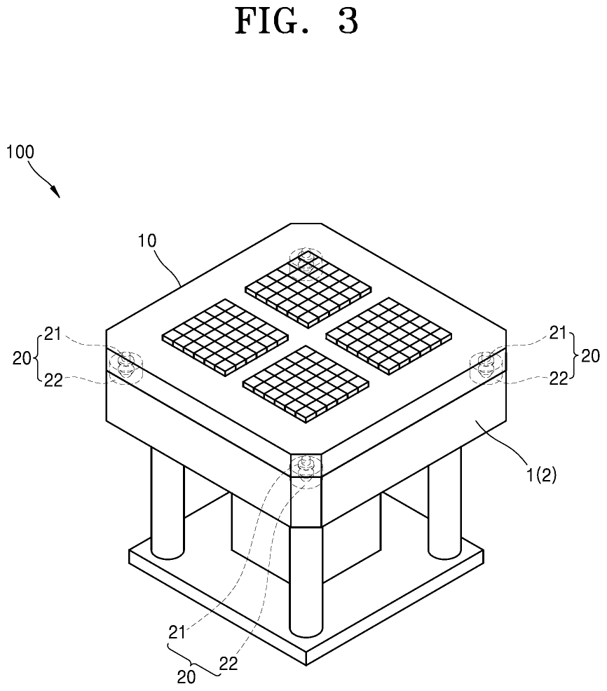

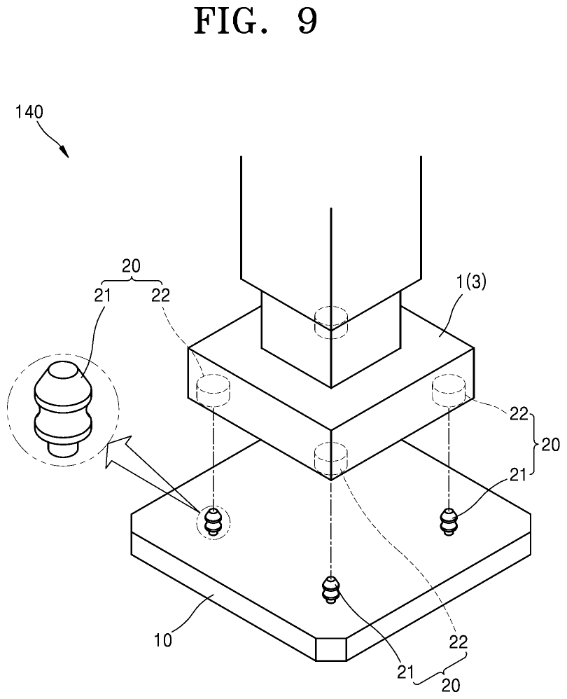

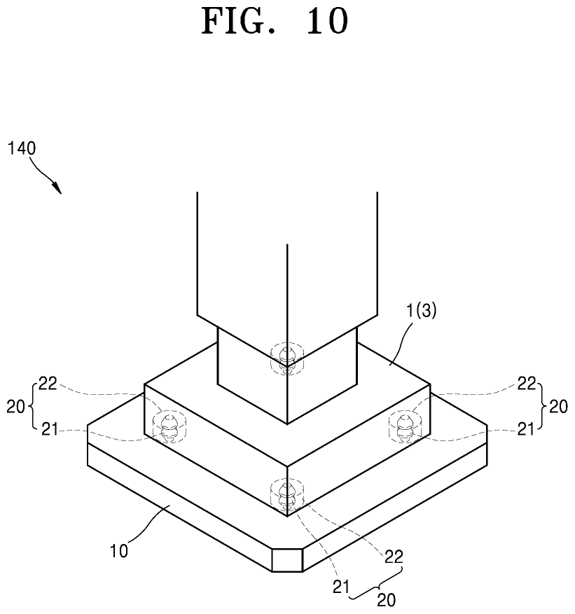

Herein, the tool changing apparatus of the present invention may be applied to, for example, a table device 2 (see FIGS. 2 and 3), e.g., the chuck table 210, a table of the cleaning and drying unit 230, the pallet table 400, the first stacker 352, the second stacker 354, or the third stacker 356, or a pickup device 3 (see FIGS. 9 and 10), e.g., the strip picker 240, the package picker 250, the first and second tray transfer units 346 and 348, or the pickers 330.

However, the semiconductor sawing and sorting apparatus 1000 to which the tool changing apparatus according to some embodiments of the present invention is applicable is not limited to the illustration, and the tool changing apparatus may be applied to semiconductor manufacturing equipments of a wide variety of configurations and forms.

FIG. 2 is an exploded perspective view of a tool changing apparatus 100 according to some embodiments of the present invention, and FIG. 3 is an assembled perspective view of the tool changing apparatus 100 of FIG. 2.

As shown in FIGS. 1 to 3, the tool changing apparatus 100 according to some embodiments of the present invention may include a target tool 10 detachably mountable on the table device 2 of the equipment 1 depending on the type or size of the semiconductor chips or the semiconductor packages P, and a coupling device 20 mounted between the equipment 1 and the target tool 10 to detachably fix the target tool 10 to the equipment 1.

Herein, the coupling device 20 may include a stud 21 mounted on the target tool 10, and a clamping module 22 mounted in the equipment 1 to selectively clamp the stud 21.

The target tool 10 may be a table structure provided with a vacuum suction line or the like, the size, shape, or specifications of which may vary depending on the type of the semiconductor packages P and, for example, four studs 21 may protrude downward from four corners of a lower surface of the target tool 10.

The clamping module 22 may be attached to or detached from the stud 21 and, for example, four clamping modules 22 may be mounted in an upper surface of the table device 2.

However, the number or configuration of the studs 21 or the clamping modules 22 may be changed or modified in various ways depending on an environment of installation, the size or volume of the target tool 10, or the like.

Therefore, according to the present invention, the target tool 10 may be easily separated from the table device 2 of the equipment 1 by controlling the stud 21 and the clamping module 22 to a free mode as shown in FIG. 2, or firmly fixed to the table device 2 of the equipment 1 by coupling the stud 21 to the clamping module 22 and then controlling the stud 21 and the clamping module 22 to a clamped mode as shown in FIG. 3.

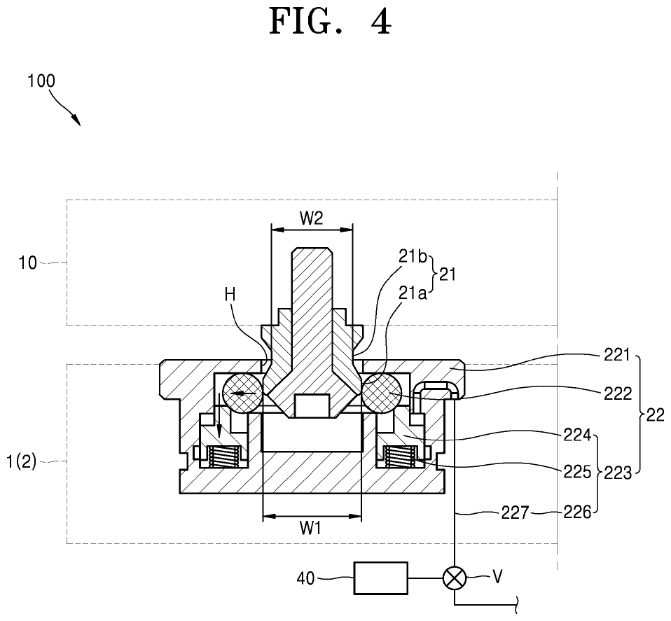

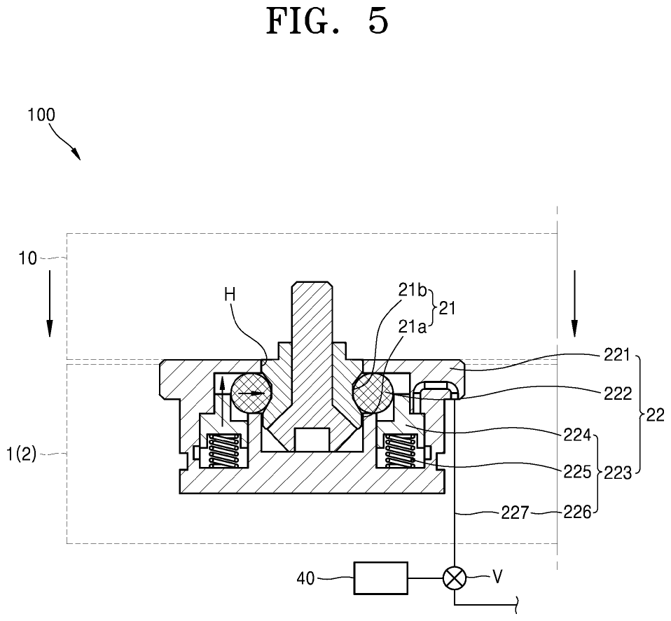

FIG. 4 is a cross-sectional view showing a free mode between the stud 21 and the clamping module 22 of the tool changing apparatus 100 of FIG. 3, and FIG. 5 is a cross-sectional view showing a clamped mode between the stud 21 and the clamping module 22 of the tool changing apparatus 100 of FIG. 4.

As shown in FIGS. 4 and 5, the stud 21 may include a head 21a provided at a front end of the stud 21 so as to be at least partially inserted into the clamping module 22, and having a first width W1, and a neck 21b provided at the rear of the head 21a and having a second width W2 less than the first width W1.

The clamping module 22 may include a module body 221 provided with a stud hole H having a shape corresponding to the stud 21 to accommodate the stud 21, a movable clamping structure 222 mounted in the module body 221 to move toward or away from the neck 21b of the stud 21 inserted into the stud hole H, and a forward/backward device 223 for moving the movable clamping structure 222 forward or backward.

The movable clamping structure 222 may be at least one ball disposed around the neck 21b of the stud 21 to press the neck 21b. Alternatively, the movable clamping structure 222 may be any of various types of movable structures, e.g., a ring, a roller, a protrusion, or a bump.

The forward/backward device 223 may include a pressing member 224 for pressing the movable clamping structure 222 at a first position to maintain a forward state and clamp the stud 21, and releasing the movable clamping structure 222 at a second position to set the stud 21 free, an elastic spring 225 for providing an elastic restoring force in a direction in which the pressing member 224 moves to the first position, and a pressing member moving device 226 for selectively moving the pressing member 224 from the first position to the second position against the elastic restoring force of the elastic spring 225.

The pressing member moving device 226 may include a pressure transmission line 227 for moving the pressing member 224 to the second position by using hydraulic or pneumatic pressure.

Therefore, as shown in FIGS. 4 and 5, operation of the tool changing apparatus 100 according to some embodiments of the present invention may be described as follows. Initially, as shown in FIG. 4, the target tool 10 provided with the stud 21 so as to be detachably mountable on the equipment 1 depending on the type or size of semiconductor chips or semiconductor packages may be placed on standby at a target position, and then the pressing member 224 may be lowered by transmitting hydraulic or pneumatic pressure to the clamping module 22, such that the stud 21 is insertable into the clamping module 22 mounted in the equipment 1. When the pressing member 224 is lowered, the movable clamping structure 222 may freely move backward to release the clamped mode to the free mode.

After that, as shown in FIG. 5, the stud 21 may be inserted into the clamping module 22 by moving the target tool 10 toward the equipment 1 or controlling the equipment 1 to move toward the target tool 10, and then the pressing member 224 may be raised by the restoring force of the elastic spring 225 by interrupting the transmission of the hydraulic or pneumatic pressure to the clamping module 22 so as to allow the clamping module 22 to clamp the stud 21. When the pressing member 224 is raised, the movable clamping structure 222 may be moved forward by the pressing member 224 to press the stud 21 and switch the free mode to the clamped mode. That is, the target tool 10 may be safely and easily mounted on the equipment 1 by firmly fixing the stud 21 to the clamping module 22.

As such, according to the present invention, tool changing operation may be automated using air clamping based on the stud 21 and the clamping module 22, user burden may be noticeably reduced because all parts of a tool may be fixed to an equipment at once by automatically moving the equipment or simply putting down or lifting the tool without a cumbersome assembly process or the like, operation safety may be greatly increased because a clamped mode may be released only while air pressure is applied, labor and time for operation may be significantly reduced even when tool weight and volume are increased, and tool designing and tool block processing may be performed easily because additional assembly holes or tabs for bolting or lockers may be omitted.

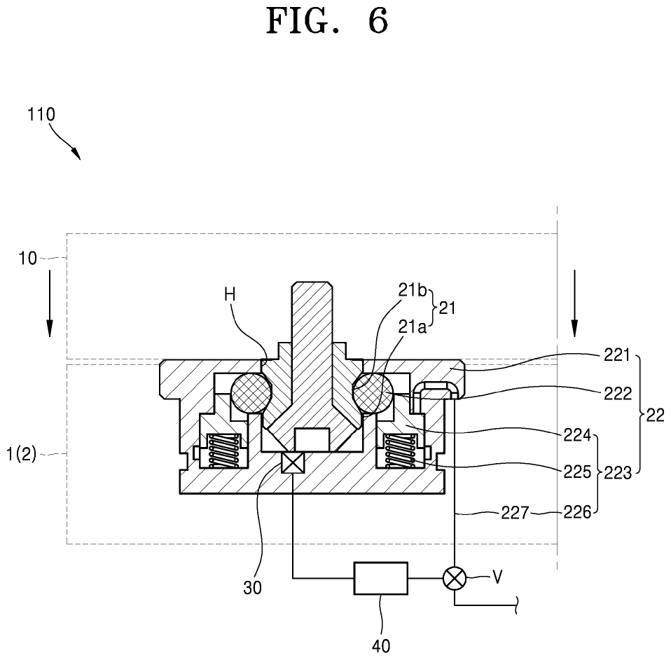

FIG. 6 is a cross-sectional view of a tool changing apparatus 110 according to other embodiments of the present invention.

As shown in FIG. 6, the tool changing apparatus 110 according to other embodiments of the present invention may further include a sensor 30 for detecting a coupling state between the stud 21 and the clamping module 22, and a controller 40 for receiving a normal coupling signal or a pressure state signal from the sensor 30 and outputting notification information or applying a control signal to a valve V of the pressure transmission line 227.

Therefore, when the sensor 30 detects the coupling state between the stud 21 and the clamping module 22 and applies an abnormal state signal to the controller 40, the controller 40 may output the notification information to various display devices or light/sound warning devices so as to be recognized by a user, or repeatedly control the valve V until a normal state signal is received.

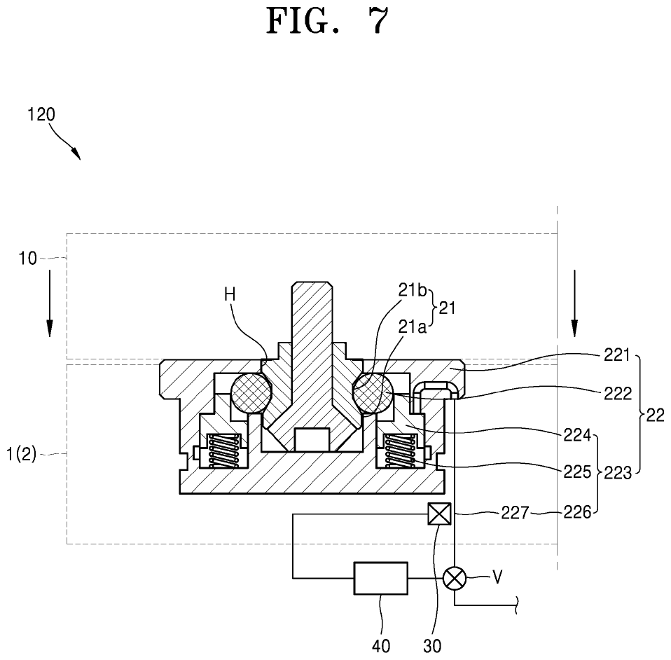

FIG. 7 is a cross-sectional view of a tool changing apparatus 120 according to other embodiments of the present invention.

As shown in FIG. 7, the tool changing apparatus 120 according to other embodiments of the present invention may further include a sensor 30 for detecting a state of the pressure transmission line 227 connected to the clamping module 22, and a controller 40 for receiving a normal coupling signal or a pressure state signal from the sensor 30 and outputting notification information.

Therefore, when the sensor 30 detects the state of the pressure transmission line 227 and applies an abnormal state signal to the controller 40, the controller 40 may output the notification information to various display devices or light/sound warning devices so as to be recognized by a user, or repeatedly control the valve V until a normal state signal is received.

As such, according to the present invention, the dropping or dislocation of a tool may be prevented because a risk factor may be identified in advance by checking a normal engagement state or a hydraulic pressure state by using the sensor 30.

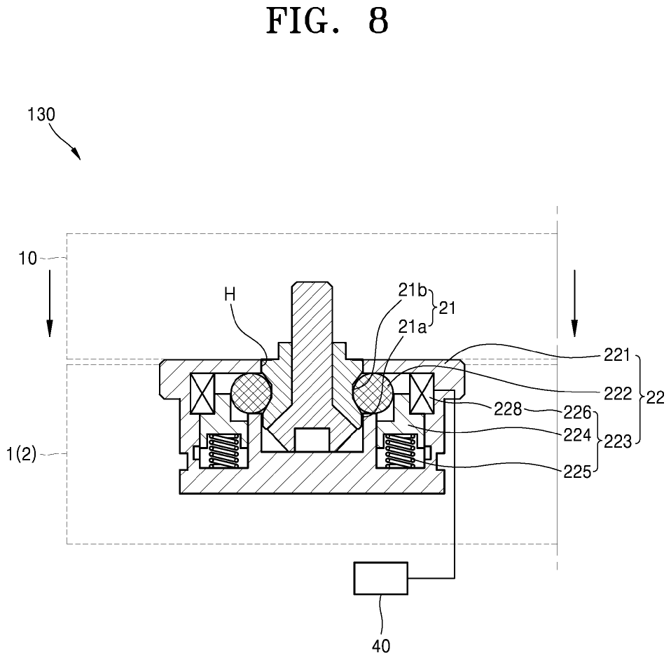

FIG. 8 is a cross-sectional view of a tool changing apparatus 130 according to other embodiments of the present invention.

As shown in FIG. 8, the pressing member moving device 226 of the tool changing apparatus 130 according to other embodiments of the present invention may include a solenoid device 228 for moving the pressing member 224 to the second position by using magnetic force.

Therefore, as shown in FIG. 8, operation of the tool changing apparatus 130 according to other embodiments of the present invention may be described as follows. The target tool 10 provided with the stud 21 so as to be detachably mountable on the equipment 1 depending on the type or size of semiconductor chips or semiconductor packages may be placed on standby at a target position, and then the pressing member 224 may be lowered by applying an electrical signal to the clamping module 22, such that the stud 21 is insertable into the clamping module 22 mounted in the equipment 1. When the pressing member 224 is lowered, the movable clamping structure 222 may freely move backward to release the clamped mode to the free mode.

After that, the stud 21 may be inserted into the clamping module 22 by moving the target tool 10 toward the equipment 1 or controlling the equipment 1 to move toward the target tool 10, and then the pressing member 224 may be raised by the restoring force of the elastic spring 225 by interrupting the application of the electrical signal to the clamping module 22 so as to allow the clamping module 22 to clamp the stud 21. When the pressing member 224 is raised, the movable clamping structure 222 may be moved forward by the pressing member 224 to press the stud 21 and switch the free mode to the clamped mode. That is, the target tool 10 may be safely and easily mounted on the equipment 1 by firmly fixing the stud 21 to the clamping module 22.

FIG. 9 is an exploded perspective view of a tool changing apparatus 140 according to other embodiments of the present invention, and FIG. 10 is an assembled perspective view of the tool changing apparatus 140 of FIG. 9.

As shown in FIGS. 9 and 10, the tool changing apparatus 140 according to other embodiments of the present invention may include the target tool 10 detachably mountable on the pickup device 3 of the equipment 1 depending on the type or size of the semiconductor chips or the semiconductor packages P, and the coupling device 20 mounted between the equipment 1 and the target tool 10 to detachably fix the target tool 10 to the equipment 1.

Herein, the coupling device 20 may include the stud 21 mounted on the target tool 10, and the clamping module 22 mounted in the equipment 1 to selectively clamp the stud 21.

The target tool 10 may be a picker structure provided with a vacuum suction line or the like, the size, shape, or specifications of which may vary depending on the type of the semiconductor packages P and, for example, four studs 21 may protrude upward from four corners of an upper surface of the target tool 10.

The clamping module 22 may be attached to or detached from the stud 21 and, for example, four clamping modules 22 may be mounted in a lower surface of the pickup device 3.

However, the number or configuration of the studs 21 or the clamping modules 22 may be changed or modified in various ways depending on an environment of installation, the size or volume of the target tool 10, or the like.

Therefore, according to the present invention, the target tool 10 may be easily separated from the pickup device 3 of the equipment 1 by controlling the stud 21 and the clamping module 22 to a free mode as shown in FIG. 9, or firmly fixed to the pickup device 3 of the equipment 1 by coupling the stud 21 to the clamping module 22 and then controlling the stud 21 and the clamping module 22 to a clamped mode as shown in FIG. 10.

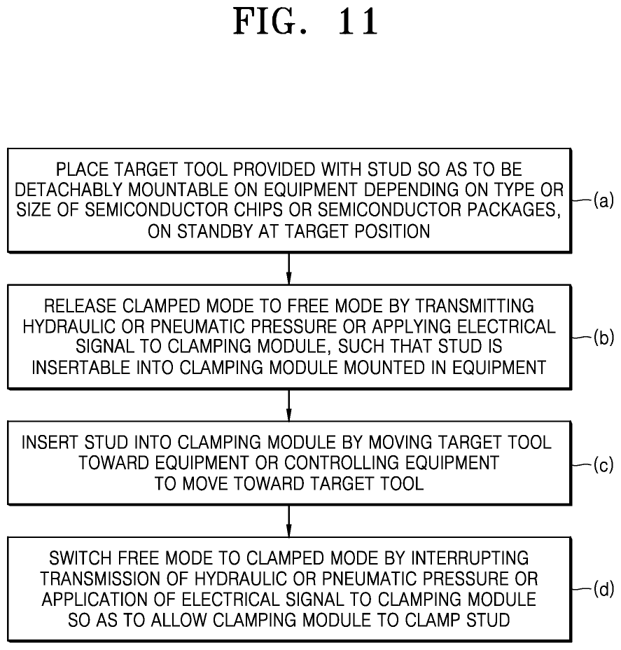

FIG. 11 is a flowchart of a tool changing method according to some embodiments of the present invention.

As shown in FIGS. 1 to 11, the tool changing method according to some embodiments of the present invention may include (a) placing the target tool 10 provided with the stud 21 so as to be detachably mountable on the equipment 1 depending on the type or size of semiconductor chips or semiconductor packages, on standby at a target position, (b) releasing a clamped mode to a free mode by transmitting a hydraulic or pneumatic pressure or applying an electrical signal to the clamping module 22, such that the stud 21 is insertable into the clamping module 22 mounted in the equipment 1, (c) inserting the stud 21 into the clamping module 22 by moving the target tool 10 toward the equipment 1 or controlling the equipment 1 to move toward the target tool 10, and (d) switching the free mode to the clamped mode by interrupting the transmission of the hydraulic or pneumatic pressure or the application of the electrical signal to the clamping module 22 so as to allow the clamping module 22 to clamp the stud 21.

According to the afore-described embodiments of the present invention, tool changing operation may be automated using air clamping based on a stud and a clamping module, user burden may be noticeably reduced because all parts of a tool may be fixed to an equipment at once by automatically moving the equipment or simply putting down or lifting the tool without a cumbersome assembly process or the like, operation safety may be greatly increased because a clamped mode may be released only while air pressure is applied, labor and time for operation may be significantly reduced even when tool weight and volume are increased, tool designing and tool block processing may be performed easily because additional assembly holes or tabs for bolting or lockers may be omitted, and the dropping or dislocation of the tool may be prevented because a risk factor may be identified in advance by checking a normal engagement state or a hydraulic pressure state by using a sensor. However, the scope of the present invention is not limited to the above effects.

While the present invention has been particularly shown and described with reference to embodiments thereof, it will be understood by one of ordinary skill in the art that various changes in form and details may be made therein without departing from the scope of the present invention as defined by the following claims.

What is claimed is:

1. A tool changing apparatus comprising:
a target tool detachably mountable on an equipment depending on a type or size of semiconductor chips or semiconductor packages; and
a coupling device mounted between the equipment and the target tool to detachably fix the target tool to the equipment,
wherein the coupling device comprises:
a stud mounted on the target tool or the equipment; and
a clamping module mounted in the equipment or the target tool to clamp the stud.

2. The tool changing apparatus of claim 1, wherein the equipment is a semiconductor sawing and sorting equipment for sawing and sorting the semiconductor chips or the semiconductor packages.

3. The tool changing apparatus of claim 1, wherein the stud comprises:
a head provided at a front end of the stud so as to be at least partially inserted into the clamping module, and having a first width; and
a neck provided at a rear of the head and having a second width less than the first width.

4. The tool changing apparatus of claim 3, wherein the clamping module comprises:
a module body provided with a stud hole having a shape corresponding to the stud to accommodate the stud;
a movable clamping structure mounted in the module body to move toward or away from the neck of the stud inserted into the stud hole; and
a forward/backward device for moving the movable clamping structure forward or backward.

5. The tool changing apparatus of claim 4, wherein the movable clamping structure is at least one of a ball, a ring, a roller, a protrusion, a bump, and combinations thereof.

6. The tool changing apparatus of claim 4, wherein the forward/backward device comprises:
a pressing member for pressing the movable clamping structure at a first position to maintain a forward state and clamp the stud, and releasing the movable clamping structure at a second position to set the stud free;
an elastic spring for providing an elastic restoring force in a direction in which the pressing member moves to the first position; and
a pressing member moving device for selectively moving the pressing member from the first position to the second position against the elastic restoring force of the elastic spring.

7. The tool changing apparatus of claim 6, wherein the pressing member moving device comprises a pressure transmission line for moving the pressing member to the second position by using hydraulic or pneumatic pressure.

8. The tool changing apparatus of claim 6, wherein the pressing member moving device comprises a solenoid device for moving the pressing member to the second position by using magnetic force.

9. The tool changing apparatus of claim 1, further comprising:
a sensor for detecting a coupling state between the stud and the clamping module or a state of a pressure transmission line connected to the clamping module; and
a controller for receiving a normal coupling signal or a pressure state signal from the sensor and outputting notification information.

10. A tool changing method comprising:
(a) placing a target tool provided with a stud so as to be detachably mountable on an equipment depending on a type or size of semiconductor chips or semiconductor packages, on standby at a target position;
(b) releasing a clamped mode to a free mode by transmitting a hydraulic or pneumatic pressure or applying an electrical signal to a clamping module, such that the stud is insertable into the clamping module mounted in the equipment;
(c) inserting the stud into the clamping module by moving the target tool toward the equipment or controlling the equipment to move toward the target tool; and
(d) switching the free mode to the clamped mode by interrupting the transmission of the hydraulic or pneumatic pressure or the application of the electrical signal to the clamping module so as to allow the clamping module to clamp the stud.
